(19) United States
(12) Patent Application Publication
(10) Pub. No.: US 2025/0079791 A1
(43) Pub. Date: Mar. 6, 2025

(54) LASER ARRAY DEVICE HAVING INDIVIDUALLY-ADDRESSABLE CATHODE

(71) Applicant: Meta Platforms Technologies, LLC, Menlo Park, CA (US)

(72) Inventors: Chloe Astrid Marie Fabien, Seattle, WA (US); Anurag Tyagi, Mill Creek, WA (US); Julia D'Rozario, Sammamish, WA (US); Christophe Antoine Hurni, Seattle, WA (US); Zhimin Shi, Bellevue, WA (US); Christopher Pynn, Seattle, WA (US)

(21) Appl. No.: 18/595,109

(22) Filed: Mar. 4, 2024

Related U.S. Application Data
(60) Provisional application No. 63/579,407, filed on Aug. 29, 2023.

(51) Int. Cl. H01S 5/042; H01S 5/02; H01S 5/20; H01S 5/30

(52) U.S. Cl. CPC H01S 5/0421; H01S 5/0208; H01S 5/2081; H01S 5/3095

(57) ABSTRACT

An optical element includes an active region overlying a substrate and disposed between an n-type layer and a p-type layer, a plurality of n-type contacts each overlying a respective portion of the n-type layer, and a p-type contact overlying the p-type layer and opposing the plurality of n-type contacts.

### CROSS-REFERENCE TO RELATED APPLICATION

This application claims the benefit of priority under 35 U.S.C. § 119 (e) of U.S. Provisional Application No. 63/579,407, filed Aug. 29, 2023, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 is a simplified schematic view showing the construction of an individually-addressable laser diode array according to various embodiments.

FIG. 2 is an example process flow for manufacturing the laser diode array of FIG. 1 according to some embodiments.

FIG. 3 is an example process flow for manufacturing the laser diode array of FIG. 1 according to further embodiments.

FIG. 4 is an example process flow for manufacturing the laser diode array of FIG. 1 according to still further embodiments.

FIG. 5 is a simplified schematic view showing the architecture of an individually-addressable laser diode array fabricated over a semi-insulating substrate according to some embodiments.

FIG. 6 illustrates the co-integration of a photonic integrated circuit with the laser diode array of FIG. 5 according to certain embodiments.

FIG. 7 shows mutually transverse cross-sectional views of a laser diode array according to further embodiments.

FIG. 8 is a simplified schematic view showing the architecture of an individually-addressable laser diode array including a tunnel junction according to some embodiments.

FIG. 9 is a schematic view showing the architecture of an individually-addressable laser diode array including an etched facet according to some embodiments.

FIG. 10 is an illustration of exemplary augmented-reality glasses that may be used in connection with embodiments of this disclosure.

FIG. 11 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

Optical displays are ubiquitous in emerging technologies, including wearable devices, smart phones, tablets, laptops, desktop computers, and other display systems. Many display systems used in such technologies are based on light-emitting diodes (LEDs), including organic light-emitting diodes (OLEDs).

In wearable devices (i.e., battery powered devices) the display typically consumes a majority of the available battery power. To extend battery life and improve brightness levels, it is desirable to reduce power consumption and produce higher luminescence emission from the light source. The present disclosure relates generally to display systems and, more specifically, to integrated low-side driver light source architectures having efficient operation and a compact form factor.

Disclosed herein are laser diode array architectures having individually-addressable emitters. Each emitter may be configured with an individually-addressable cathode and a shared or dedicated anode. An emitter array may include, for example, 8 diodes per primary color that are arranged in a commercially-relevant form factor. The emitters may be disposed at a pitch of 10 micrometers or less, for example. With individually-addressable cathodes, the laser diode array may be operable using an integrated low-side driver, which may provide improved power efficiency relative to comparative systems.

In accordance with some embodiments, a light source includes a plurality of laser diodes disposed between an n-type layer and a p-type layer, a plurality of n-type contacts overlying the n-type layer, where each n-type contact overlies a respective one of the plurality of laser diodes, and a plurality of p-type contacts overlying the p-type layer opposite to the plurality of n-type contacts. In accordance with some embodiments, a light source includes a plurality of laser diodes disposed between an n-type layer and a p-type layer, a plurality of n-type contacts overlying the n-type layer, where each n-type contact overlies a respective one of the plurality of laser diodes, and a single common p-type contact overlying the p-type layer opposite to the plurality of n-type contacts.

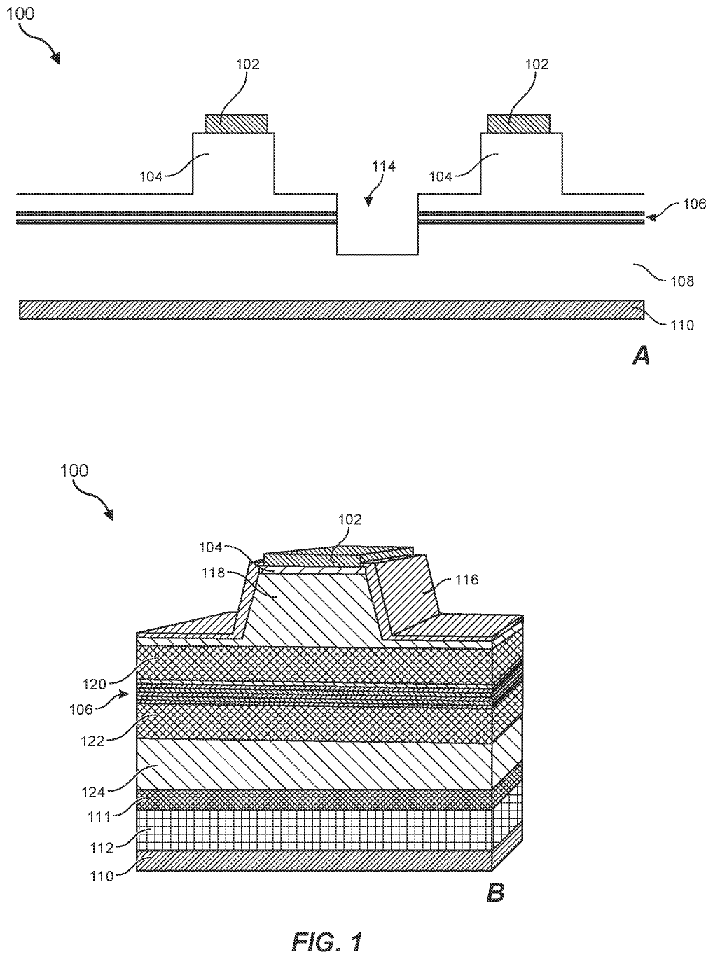

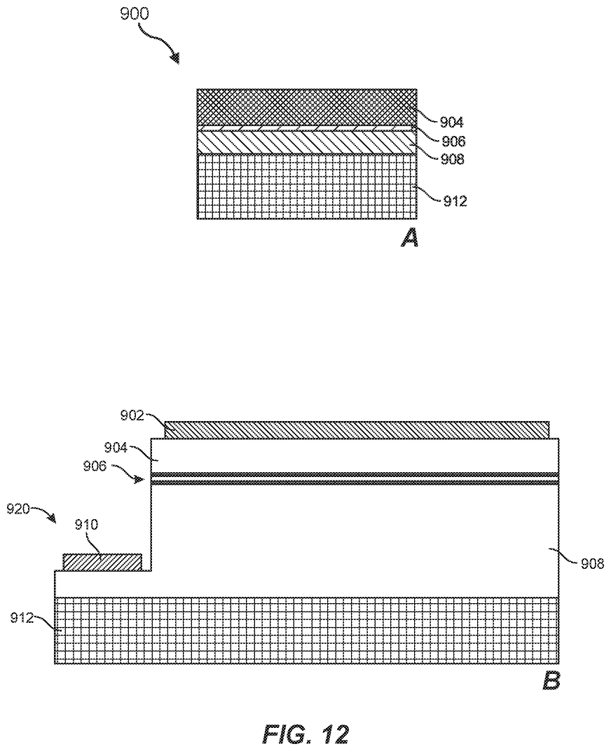

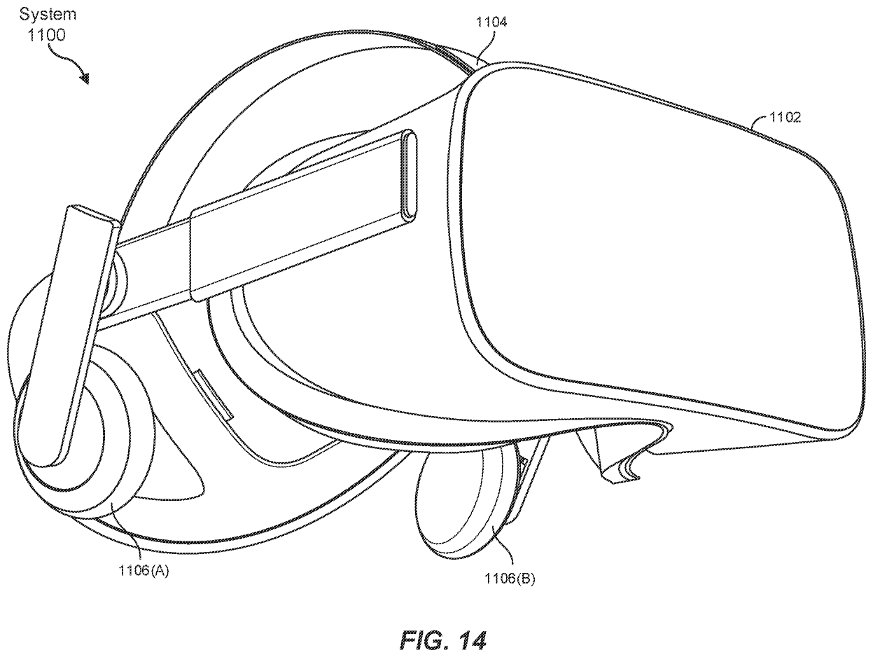

The following will provide, with reference to FIGS. 1-11, detailed descriptions of systems and related methods associated with a laser array device architecture having a plurality of individually-addressable cathodes. The discussion associated with FIGS. 1-9 includes a description of example methods of manufacturing an individually-addressable multi-emitter structure having dedicated anodes or a common anode. The discussion associated with FIGS. 10 and 11 relates to exemplary virtual reality and augmented reality devices that may include one or more light source modules as disclosed herein.

A scanning augmented reality (AR) display may be configured to have a high field of view (FOV), high resolution and high frame rate, and may include a light source module having a plurality of individually-addressable multi-emitter sources. A light source may include an edge-emitting laser, superluminescent diode (SLED), vertical cavity surface-emitting laser (VCSEL), etc. An example light source may include multiple diodes, e.g., 8 emitters per color, that are arrayed with a predetermined spacing on a suitable substrate.

An AR display may additionally include a display driver that is co-integrated within the light source module. Characteristics of a suitable display driver may include 1-3 ns pulse width operation within an approximately 5 ns clock tick interval and may be configured to provide a variable optical pulse energy. A display driver may be configured to support a multi-channel, individually-addressable light source module with maximum power efficiency in a commercially-relevant form factor. In certain embodiments, the display driver may be configured as a low-side driver.

As used herein, a high-side or low-side driver refers to an electronic circuit that is used to control the switching of a load such as a laser diode. A high-side driver is configured to switch at the high-side of the load, whereas a low-side driver is configured to switch at the low-side of the load. That is, a switch placed in the upper circuit with respect to an external load is referred to as high-side drive (power supply side), and when mounted in the lower circuit is called low-side drive (ground side). Thus, a high-side driver is adapted to switch a voltage that is higher than its own supply voltage, whereas a low-side driver is adapted to switch a voltage that is at or below its own supply voltage.

Without wishing to be bound by theory, low-side switching may be beneficially used when power to a load is controlled through (relatively) high-speed pulse width modulation. A low-side driver may advantageously decrease power consumption within an associated device or system, for example. As disclosed herein, and in accordance with various embodiments, by configuring a laser array device to include a plurality of (n-type) cathodes, a low-side driver configuration may be enabled, which may result in the driver having improved power efficiency.

The manufacture of a laser array device having individually-addressable cathodes, including exemplary structures, is described with reference to FIGS. 1-9. A laser diode having a common p-type contact is shown schematically in FIG. 1. Referring to FIG. 1A, laser diode array 100 includes a common p-type contact 110 (anode) and a plurality of n-type contacts 102 (cathodes). As used herein, “p-type” refers to a semiconductor material where the addition of impurities (dopant) creates a deficiency of valence electrons, whereas “n-type” refers to a semiconductor material where the addition of impurities creates free electrons within the material. Doping changes the electron and hole carrier concentrations of a host material at thermal equilibrium. Thus, a doped semiconductor material may be p-type or n-type.

In some embodiments, a layer of semiconductor material, including a layer of doped semiconductor material, may be formed using an epitaxial growth process. As used herein, the terms “epitaxy,” “epitaxial” and/or “epitaxial growth and/or deposition” refer to the nucleation and growth of a semiconductor layer on a deposition surface where the semiconductor layer being grown assumes the same crystalline habit as the material of the deposition surface. For example, in an epitaxial deposition process, chemical reactants may be controlled, and the system parameters may be set so that depositing atoms or molecules alight on the deposition surface and remain sufficiently mobile via surface diffusion to orient themselves according to the crystalline orientation of the atoms or molecules of the deposition surface. An epitaxial process may be homogeneous or heterogeneous.

In FIG. 1A, laser diode array 100 may include an active region 106 disposed between an n-type layer 104 and a p-type layer 108. An n-type contact 102 may overlie a portion of the n-type layer 104, and a common p-type contact 110 may overlie the p-type layer 108, opposing the n-type contact 102. An isolation groove 114 may be located between neighboring n-type contacts 102. The isolation groove 114 may extend entirely through the active region 106 and partially through p-type layer 108. An isolation groove may be filled or partially filled (i.e., lined) with any suitable dielectric including an organic or inorganic medium. A representative stack architecture of the laser diode array 100 is shown in FIG. 1B.

As shown in FIG. 1B, the laser diode array 100 may include, from bottom to top, a backside p-type contact 110, a semiconductor substrate 112, a strain-compensation layer 111, a p-cladding layer 124, a p-waveguiding layer 122, the active region 106, an n-waveguiding layer 120, an n-cladding layer 118, a n-type layer 104, a field insulator 116, and the plurality of n-type contacts 102. P-cladding layer 124 and p-waveguiding layer 122 may have a higher refractive index than n-cladding layer 118 and n-waveguiding layer 120 to provide optical and electrical confinement for the emitted light to create an optical barrier.

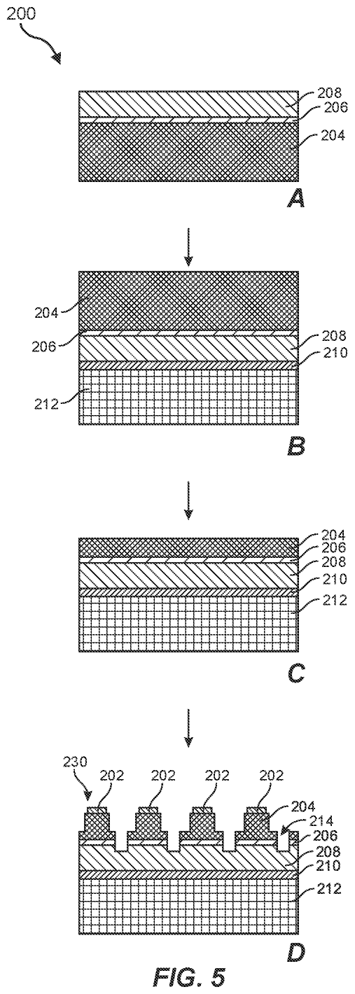

According to some embodiments, a simplified process flow 200 for manufacturing a laser diode array 100 of FIG. 1 is illustrated in FIGS. 2A-2D. Referring to FIG. 2A, a multi-quantum well (MQW) may be formed in an active region 206 between an n-type layer 204 and a p-type layer 208. As shown in FIG. 2B, the foregoing structure may be flipped and bonded via a common p-type contact 210 to a substrate 212. Following thinning of the n-type layer 204, as shown in FIG. 2C, individual n-type contacts 202 may be formed and defined over the n-type layer 204, as shown in FIG. 2D. Singulation of the n-type contacts may include formation of isolation grooves 214 between discrete laser diodes 230 may provide electrical and optical isolation.

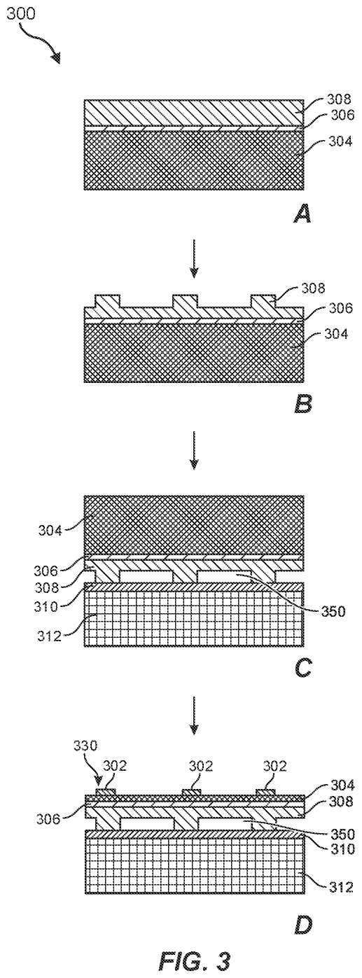

Turning now to FIGS. 3A-3D, illustrated is a further process flow 300 for forming a laser array device having a common p-type contact 310 (e.g., anode). In FIG. 3A, a multi-quantum well (MQW) may be formed in an active region 306 between an n-type layer 304 and a p-type layer 308. In the embodiment illustrated in FIG. 3B, additional processing may be performed on the p-type layer 308, e.g., to provide lateral confinement of the laser diodes 330. As illustrated in FIG. 3C, the structure of FIG. 3B may be bonded to a substrate 312 via a common p-type contact 310. Following thinning of the n-type layer 304, individual n-type contacts 302 may be formed and define individual laser diodes 330, as illustrated in FIG. 3D. For instance, the individual laser diodes 330 may be separated by an air-gap 350.

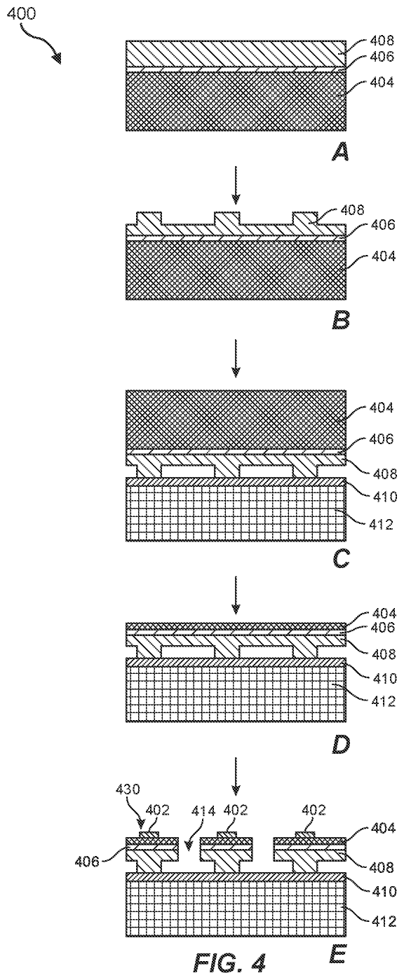

A still further process flow 400 for forming a laser diode array is shown in FIGS. 4A-4E. The laser diode array includes individual n-type contacts and a common p-type contact. Referring to FIG. 4A, a multi-quantum well (MQW) may be formed in an active region 406 between an n-type layer 404 and a p-type layer 408. Referring to FIG. 4B, additional processing may be performed on the p-type layer 408, e.g., to provide lateral confinement between adjacent laser diodes 430.

The acts of bonding a common p-type contact 410 and substrate 412 and thinning the n-type layer 404 are illustrated in FIGS. 4C and 4D, respectively. Individual n-type contacts 402 may be formed over respective regions of the n-type layer 404. Individually addressable laser diodes 430 may be separated by the etching entirely through the n-type layer 404, the active region 406, and the p-type layer 408 to form isolation grooves 414, as shown in FIG. 4E.

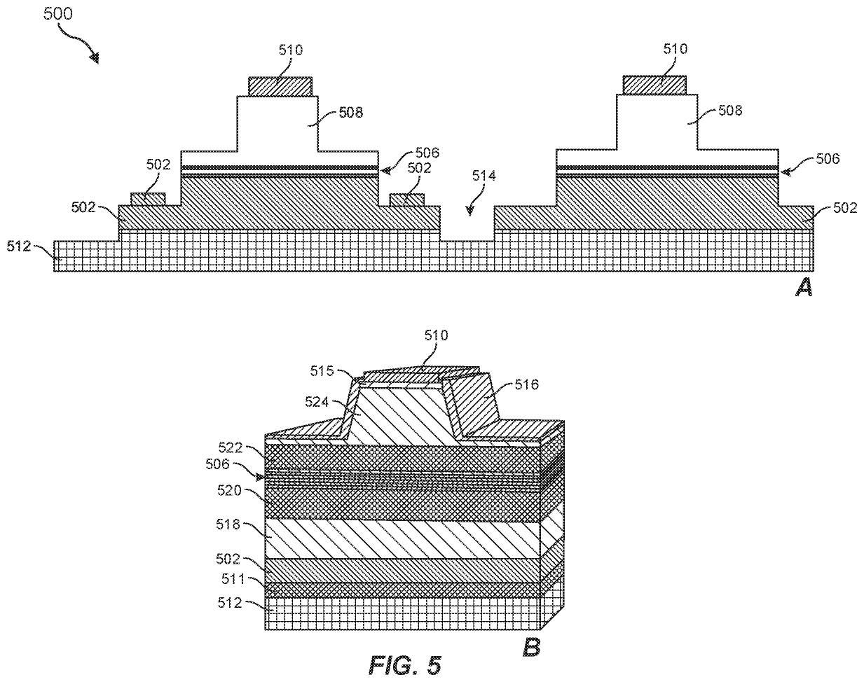

Referring to FIG. 5, shown is a schematic representation of a portion of a laser diode array. Referring to FIG. 5A, laser diode array 500 includes individual devices having first and second n-type contacts 502 and a single p-type contact 510. The laser diode array may be formed over a semi-insulating substrate 512 and may include more than a single n-type contact (cathode) per diode. For example, the first and second n-type contacts 502 may overly respective portions of n-type layer 504 and may be located adjacent to an active region 506. In this manner, a p-type contact 510 may be laterally offset from each of the n-type contacts 502 and overlie p-type layer 508. Relative to a laser diode array having a single n-type contact per diode, a structure that includes plural n-type contacts 502 may exhibit improved charge injection and better performance. An isolation groove 514 extending entirely through n-type layer 504 and partially through semi-insulating substrate 512 may be disposed between adjacent devices.

Referring to FIG. 5B, a representative stack architecture is also shown. The stack architecture array may include, from bottom to top, a semi-insulating substrate 512, a strain compensation layer 511, an n-type contact 502, an n-cladding layer 518, an n-waveguiding layer 520, the active region 506, a p-waveguiding layer 522, a p-cladding layer 524, a field insulator 516, a contact layer 515, and a p-type contact 510. In some embodiments, a current blocking layer (not shown) may be disposed between the n-cladding layer 518 and the strain compensation layer 511.

In some embodiments, a laser diode array, such as the laser diode arrays 100 and 500, may be co-integrated with a photonic integrated circuit (PIC). A photonic integrated circuit may include light guiding channels fabricated in 2D or 3D architectures. The light guiding channels can include ridge waveguides, rib waveguides, multi-ridge/rib waveguides, or gradient index waveguides (e.g., formed using ion diffusion, polymerization, direct laser writing/exposure, etc.).

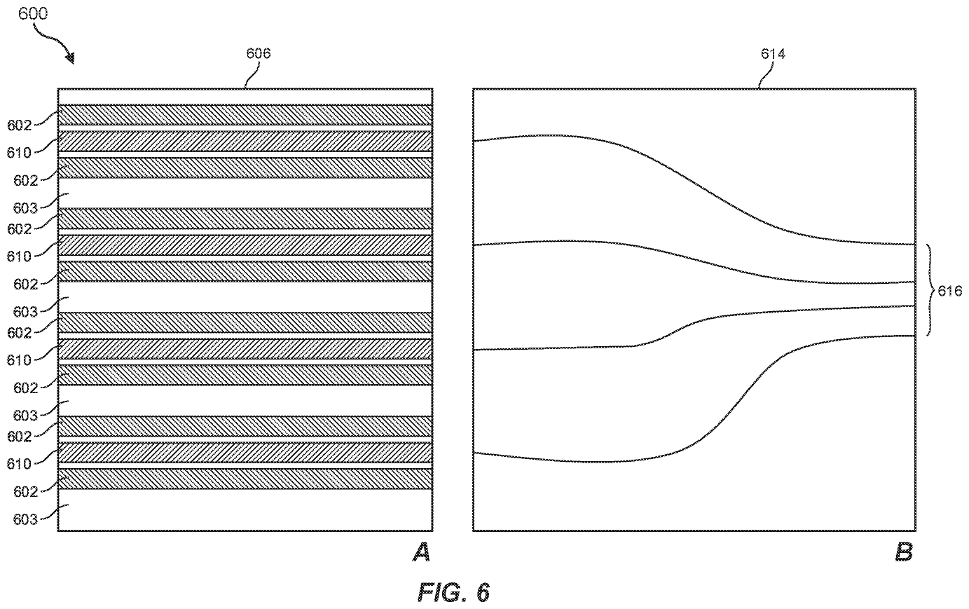

Shown schematically in FIG. 6 is a top view of a photonic integrated circuit 900. Light emitted from the laser diode array 606 may be coupled into PIC 614 in a manner effective to decrease the inter emission point pitch, e.g., to a pitch 616 less than approximately 10 micrometers. Coupling between the laser diode array 606 and the PIC 614 can include various coupling mechanisms, including micro-lenses, photonic wire bonding, mode converters, and the like.

In the illustrated embodiment, a length of an individual n-type contact 602 and a common p-type contact 610 may be substantially equal to a corresponding areal dimension (e.g., length or width) of the associated die 603.

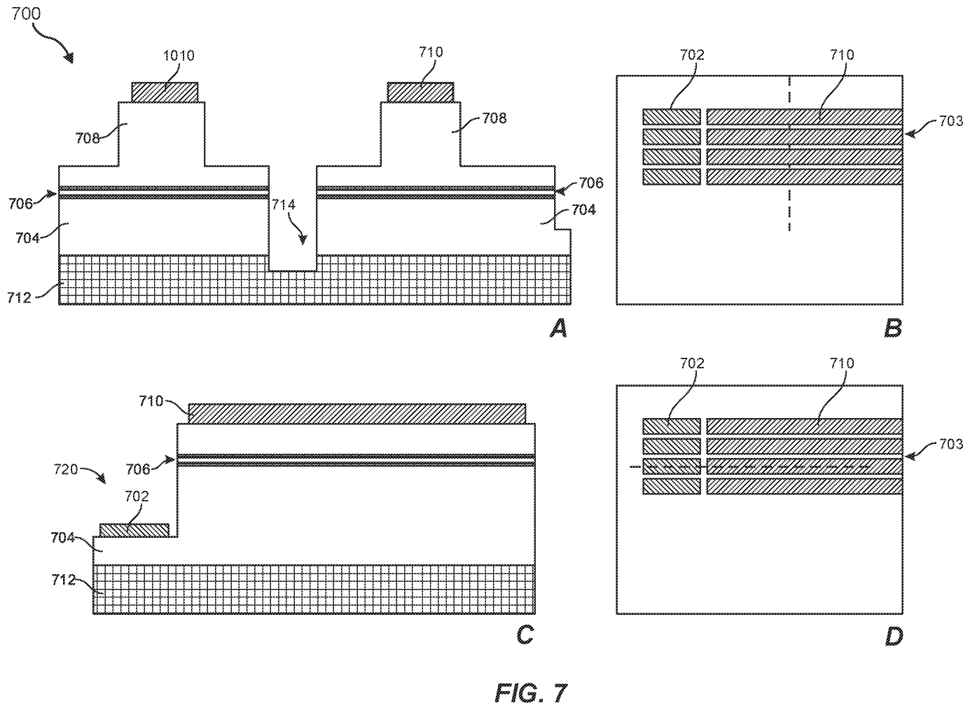

A laser diode array may include a semi-insulating substrate that is adapted to inhibit current flow between adjacent emitters during use. Referring to FIG. 7, shown are mutually transverse cross-sectional views and accompanying plan views of an example laser diode array 700. FIG. 7A is a cross-sectional view depicting a series of p-type contacts associated with a succession of diodes, as illustrated in the corresponding layout shown in FIG. 7B, and FIG. 7C is a cross-sectional view depicting the relationship between the p-type contact and n-type contact for each individual diode, as illustrated in the corresponding layout shown in FIG. 7D.

The diode architecture includes a semi-insulating substrate 712 and an active area 706 disposed over the substrate and between n-type layer 704 and p-type layer 708. Between adjacent devices, an isolation groove 714 extends through the p-type layer 708, the active area 706, and the n-type layer 704, and partially through the semi-insulating substrate 712. Isolation groove 714 may be configured to provide thermal, electrical, and/or optical isolation between adjacent devices. As shown in FIG. 7C, n-type contact 702 may be formed on a facet 720 that is etched in the n-type layer 704.

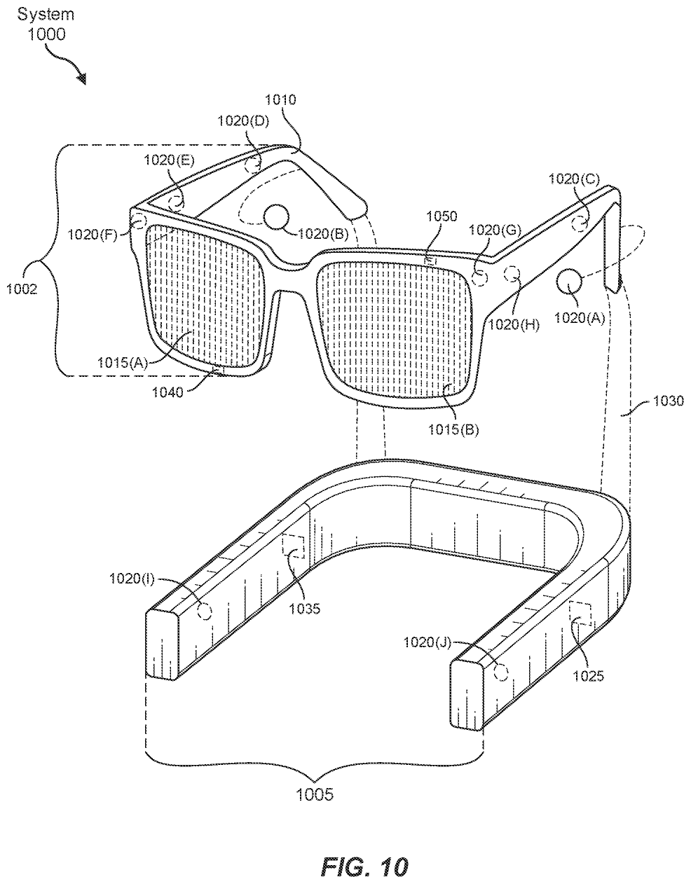

Referring to FIG. 8A, a laser diode array 800 may include a tunnel junction 810. Formation of a tunnel junction 810 may obviate the need for an etch process to create a facet (e.g., etched facet 720). Contact to a common p-type contact may be made instead through the substrate 812. N-type contacts 802 may be formed using n-side processing without flipping the structure. Active layer 806 is disposed between an n-type layer 804 and a p-type layer 808, where individual n-type contacts 802 may form over portions of the n-type layer 804 to form the individually addressable laser diodes 830 that are separated by isolation grooves 814, as shown in FIG. 8B.

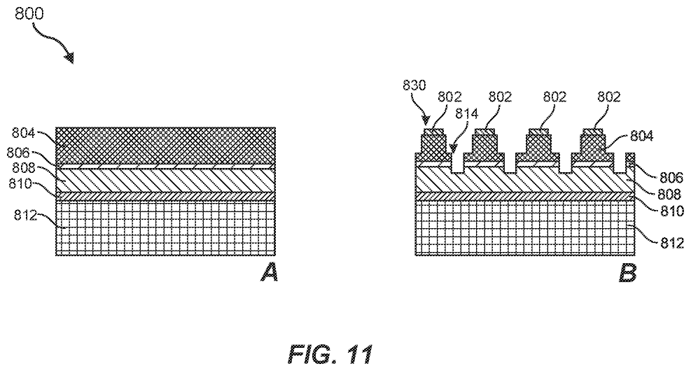

Referring to FIG. 9, shown is a portion of a laser diode array having an inverted epitaxial structure. As shown in FIG. 9A, laser diode 900 includes, from top to bottom, a n-type layer 904, an active region 906, and a p-type layer 908 formed over substrate 912. As shown in FIG. 9B, an n-type contact 902 may be formed over n-type layer 904 and a p-type contact may be formed over an etched facet 920 that is formed in p-type layer 908.

Disclosed are manufacturing methods and associated device architectures for a laser diode array having a common anode and individually-addressable emitters. An emitter array may include, for example, 8 diodes per primary color that are arranged in a commercially-relevant form factor. The diodes may be disposed at a pitch of approximately 10 micrometers or less, e.g., 5 micrometers. With a individually-addressable cathodes, the laser diode array may be operable using an integrated low-side driver, which may provide improved power efficiency relative to a system having a high-side driver. Various methods may be used to form the laser diode array, including semiconductor processing platforms such as chemical vapor deposition, epitaxial deposition and growth, and plasma etching.

### EXAMPLE EMBODIMENTS

Example 1: An optical element includes an active region overlying a substrate and disposed between an n-type layer and a p-type layer, a plurality of n-type contacts each overlying a respective portion of the n-type layer, and a p-type contact overlying the p-type layer and opposing the plurality of n-type contacts.

Example 2: The optical element of Example 1, where the active region includes

a multi-quantum well.

Example 3: The optical element of any of Examples 1 and 2, where the active region includes a plurality of laser diodes.

Example 4: The optical element of any of Examples 1-3, where the n-type layer includes a segmented layer defining a plurality of individually-addressable laser diodes.

Example 5: The optical element of any of Examples 1-4, further including an isolation groove located between neighboring n-type contacts.

Example 6: The optical element of any of Examples 1-5, further including an isolation groove located between neighboring n-type contacts, where the isolation groove extends entirely through the active region.

Example 7: The optical element of any of Examples 1-6, further including a driver circuit.

Example 8: The optical element of Example 7, where the driver circuit is configured as a low-side driver.

Example 9: The optical element of any of Examples 7 and 8, where the driver circuit is configured as a high-side driver.

Example 10: The optical element of any of Examples 1-9, further including a tunnel junction located between the p-type layer and the substrate.

Example 11: An optical element including a region disposed between an n-type layer and a p-type layer, the active region overlying a substrate, a first n-type contact and a second n-type contact overlying respective portions of the n-type layer, where the first and second n-type contacts are each located adjacent to the active region, and a common p-type contact overlying the p-type layer, where the common p-type contact is laterally offset from each of the n-type contacts.

Example 12: The optical element of Example 11, where the active region includes a plurality of laser diodes.

Example 13: The optical element of any of Examples 11 and 12, where the substrate includes a semi-insulating material.

Example 14: The optical element of any of Examples 11-13, further including an isolation groove extending entirely through the n-type layer and located peripheral to the active region.

Example 15: The optical element of any of Examples 11-14, where the n-type layer includes a mesa located peripheral to the active region and the first and second n-type contacts are disposed over respective portions of the mesa.

Example 16: The optical element of Example 15, further including an isolation groove located adjacent to the mesa.

Example 17: The optical element of any of Examples 15 and 16, where the isolation groove extends partially through the substrate.

Example 18: A method including (i) forming an active region between an n-type layer and a p-type layer, (ii) forming a p-type contact over a substrate, (iii) bonding the p-type layer to the p-type contact, (iv) etching entirely through the n-type layer and the active region and partially through the p-type layer to form a plurality of isolated structures, and (v) forming an n-type contact over the n-type layer in each isolated structure to form a plurality of laser diodes, where each of the plurality of laser diodes is electrically connected to the p-type contact.

Example 19: The method of Example 18, further including thinning the n-type layer prior to etching through the n-type layer.

Example 20: The method of any of Examples 18 and 19, where etching entirely through the n-type layer and the active region and partially through the p-type layer includes an anisotropic etch.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 1000 in FIG. 10) or that visually immerses a user in an artificial reality (e.g., virtual-reality system 1100 in FIG. 11). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 10, augmented-reality system 1000 may include an eyewear device 1002 with a frame 1010 configured to hold a left display device 1015(A) and a right display device 1015(B) in front of a user's eyes. Display devices 1015(A) and 1015(B) may act together or independently to present an image or series of images to a user. While augmented-reality system 1000 includes two displays, embodiments of this disclosure may be implemented in augmented-reality systems with a single NED or more than two NEDs.

In some embodiments, augmented-reality system 1000 may include one or more sensors, such as sensor 1040. Sensor 1040 may generate measurement signals in response to motion of augmented-reality system 1000 and may be located on substantially any portion of frame 1010. Sensor 1040 may represent a position sensor, an inertial measurement unit (IMU), a depth camera assembly, a structured light emitter and/or detector, or any combination thereof. In some embodiments, augmented-reality system 1000 may or may not include sensor 1040 or may include more than one sensor. In embodiments in which sensor 1040 includes an IMU, the IMU may generate calibration data based on measurement signals from sensor 1040. Examples of sensor 1040 may include, without limitation, accelerometers, gyroscopes, magnetometers, other suitable types of sensors that detect motion, sensors used for error correction of the IMU, or some combination thereof.

Augmented-reality system 1000 may also include a microphone array with a plurality of acoustic transducers 1020(A)-1020(J), referred to collectively as acoustic transducers 1020. Acoustic transducers 1020 may be transducers that detect air pressure variations induced by sound waves. Each acoustic transducer 1020 may be configured to detect sound and convert the detected sound into an electronic format (e.g., an analog or digital format). The microphone array in FIG. 10 may include, for example, ten acoustic transducers: 1020(A) and 1020(B), which may be designed to be placed inside a corresponding ear of the user, acoustic transducers 1020(C), 1020(D), 1020(E), 1020(F), 1020(G), and 1020(H), which may be positioned at various locations on frame 1010, and/or acoustic transducers 1020(I) and 1020(J), which may be positioned on a corresponding neckband 1005.

In some embodiments, one or more of acoustic transducers 1020(A)-(F) may be used as output transducers (e.g., speakers). For example, acoustic transducers 1020(A) and/or 1020(B) may be earbuds or any other suitable type of headphone or speaker.

The configuration of acoustic transducers 1020 of the microphone array may vary. While augmented-reality system 1000 is shown in FIG. 10 as having ten acoustic transducers 1020, the number of acoustic transducers 1020 may be greater or less than ten. In some embodiments, using higher numbers of acoustic transducers 1020 may increase the amount of audio information collected and/or the sensitivity and accuracy of the audio information. In contrast, using a lower number of acoustic transducers 1020 may decrease the computing power required by an associated controller 1050 to process the collected audio information. In addition, the position of each acoustic transducer 1020 of the microphone array may vary. For example, the position of an acoustic transducer 1020 may include a defined position on the user, a defined coordinate on frame 1010, an orientation associated with each acoustic transducer 1020, or some combination thereof.

Acoustic transducers 1020(A) and 1020(B) may be positioned on different parts of the user's ear, such as behind the pinna, behind the tragus, and/or within the auricle or fossa. Or, there may be additional acoustic transducers 1020 on or surrounding the ear in addition to acoustic transducers 1020 inside the ear canal. Having an acoustic transducer 1020 positioned next to an ear canal of a user may enable the microphone array to collect information on how sounds arrive at the ear canal. By positioning at least two of acoustic transducers 1020 on either side of a user's head (e.g., as binaural microphones), augmented-reality system 1000 may simulate binaural hearing and capture a 3D stereo sound field around about a user's head. In some embodiments, acoustic transducers 1020(A) and 1020(B) may be connected to augmented-reality system 1000 via a wired connection 1030, and in other embodiments acoustic transducers 1020(A) and 1020(B) may be connected to augmented-reality system 1000 via a wireless connection (e.g., a Bluetooth connection). In still other embodiments, acoustic transducers 1020(A) and 1020(B) may not be used at all in conjunction with augmented-reality system 1000.

Acoustic transducers 1020 on frame 1010 may be positioned along the length of the temples, across the bridge, above or below display devices 1015(A) and 1015(B), or some combination thereof. Acoustic transducers 1020 may be oriented such that the microphone array is able to detect sounds in a wide range of directions surrounding the user wearing the augmented-reality system 1000. In some embodiments, an optimization process may be performed during manufacturing of augmented-reality system 1000 to determine relative positioning of each acoustic transducer 1020 in the microphone array.

In some examples, augmented-reality system 1000 may include or be connected to an external device (e.g., a paired device), such as neckband 1005. Neckband 1005 generally represents any type or form of paired device. Thus, the following discussion of neckband 1005 may also apply to various other paired devices, such as charging cases, smart watches, smart phones, wrist bands, other wearable devices, hand-held controllers, tablet computers, laptop computers, other external compute devices, etc.

As shown, neckband 1005 may be coupled to eyewear device 1002 via one or more connectors. The connectors may be wired or wireless and may include electrical and/or non-electrical (e.g., structural) components. In some cases, eyewear device 1002 and neckband 1005 may operate independently without any wired or wireless connection between them. While FIG. 10 illustrates the components of eyewear device 1002 and neckband 1005 in example locations on eyewear device 1002 and neckband 1005, the components may be located elsewhere and/or distributed differently on eyewear device 1002 and/or neckband 1005. In some embodiments, the components of eyewear device 1002 and neckband 1005 may be located on one or more additional peripheral devices paired with eyewear device 1002, neckband 1005, or some combination thereof.

Pairing external devices, such as neckband 1005, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1000 may be provided by a paired device or shared between a paired device and an eyewear device, thus reducing the weight, heat profile, and form factor of the eyewear device overall while still retaining desired functionality. For example, neckband 1005 may allow components that would otherwise be included on an eyewear device to be included in neckband 1005 since users may tolerate a heavier weight load on their shoulders than they would tolerate on their heads. Neckband 1005 may also have a larger surface area over which to diffuse and disperse heat to the ambient environment. Thus, neckband 1005 may allow for greater battery and computation capacity than might otherwise have been possible on a stand-alone eyewear device. Since weight carried in neckband 1005 may be less invasive to a user than weight carried in eyewear device 1002, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1005 may be communicatively coupled with eyewear device 1002 and/or to other devices. These other devices may provide certain functions (e.g., tracking, localizing, depth mapping, processing, storage, etc.) to augmented-reality system 1000. In the embodiment of FIG. 10, neckband 1005 may include two acoustic transducers (e.g., 1020(I) and 1020(J)) that are part of the microphone array (or potentially form their own microphone subarray). Neckband 1005 may also include a controller 1025 and a power source 1035.

Acoustic transducers 1020(I) and 1020(J) of neckband 1005 may be configured to detect sound and convert the detected sound into an electronic format (analog or digital). In the embodiment of FIG. 10, acoustic transducers 1020(I) and 1020(J) may be positioned on neckband 1005, thereby increasing the distance between the neckband acoustic transducers 1020(I) and 1020(J) and other acoustic transducers 1020 positioned on eyewear device 1002. In some cases, increasing the distance between acoustic transducers 1020 of the microphone array may improve the accuracy of beamforming performed via the microphone array. For example, if a sound is detected by acoustic transducers 1020(C) and 1020(D) and the distance between acoustic transducers 1020(C) and 1020(D) is greater than, e.g., the distance between acoustic transducers 1020(D) and 1020(E), the determined source location of the detected sound may be more accurate than if the sound had been detected by acoustic transducers 1020(D) and 1020(E).

Controller 1025 of neckband 1005 may process information generated by the sensors on neckband 1005 and/or augmented-reality system 1000. For example, controller 1025 may process information from the microphone array that describes sounds detected by the microphone array. For each detected sound, controller 1025 may perform a direction-of-arrival (DOA) estimation to estimate a direction from which the detected sound arrived at the microphone array. As the microphone array detects sounds, controller 1025 may populate an audio data set with the information. In embodiments in which augmented-reality system 1000 includes an inertial measurement unit, controller 1025 may compute all inertial and spatial calculations from the IMU located on eyewear device 1002. A connector may convey information between augmented-reality system 1000 and neckband 1005 and between augmented-reality system 1000 and controller 1025. The information may be in the form of optical data, electrical data, wireless data, or any other transmittable data form. Moving the processing of information generated by augmented-reality system 1000 to neckband 1005 may reduce weight and heat in eyewear device 1002, making it more comfortable to the user.

Power source 1035 in neckband 1005 may provide power to eyewear device 1002 and/or to neckband 1005. Power source 1035 may include, without limitation, lithium ion batteries, lithium-polymer batteries, primary lithium batteries, alkaline batteries, or any other form of power storage. In some cases, power source 1035 may be a wired power source. Including power source 1035 on neckband 1005 instead of on eyewear device 1002 may help better distribute the weight and heat generated by power source 1035.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1100 in FIG. 11, that mostly or completely covers a user's field of view. Virtual-reality system 1100 may include a front rigid body 1102 and a band 1104 shaped to fit around a user's head. Virtual-reality system 1100 may also include output audio transducers 1106(A) and 1106(B). Furthermore, while not shown in FIG. 11, front rigid body 1102 may include one or more electronic elements, including one or more electronic displays, one or more inertial measurement units (IMUs), one or more tracking emitters or detectors, and/or any other suitable device or system for creating an artificial reality experience.

Artificial-reality systems may include a variety of types of visual feedback mechanisms. For example, display devices in augmented-reality system 1000 and/or virtual-reality system 1100 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 1000 and/or virtual-reality system 1100 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented reality system 1000 and/or virtual-reality system 1100 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 11, output audio transducers 1106(A) and 1106(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 10, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a lens that comprises or includes polycarbonate include embodiments where a lens consists essentially of polycarbonate and embodiments where a lens consists of polycarbonate.

What is claimed is:

1. An optical element comprising:
an active region overlying a substrate and disposed between an n-type layer and a p-type layer;
a plurality of n-type contacts each overlying a respective portion of the n-type layer; and
a p-type contact overlying the p-type layer and opposing the plurality of n-type contacts.

2. The optical element of claim 1, wherein the active region comprises a multi-quantum well.

3. The optical element of claim 1, wherein the active region comprises a plurality of laser diodes.

4. The optical element of claim 1, wherein the n-type layer comprises a segmented layer defining a plurality of individually-addressable laser diodes.

5. The optical element of claim 1, further comprising an isolation groove located between neighboring n-type contacts.

6. The optical element of claim 1, further comprising an isolation groove located between neighboring n-type contacts, wherein the isolation groove extends entirely through the active region.

7. The optical element of claim 1, further comprising a driver circuit.

8. The optical element of claim 7, wherein the driver circuit is configured as a low-side driver.

9. The optical element of claim 7, wherein the driver circuit is configured as a high-side driver.

10. The optical element of claim 1, further comprising a tunnel junction located between the p-type layer and the substrate.

11. An optical element comprising:
an active region disposed between an n-type layer and a p-type layer, the active region overlying a substrate;
a first n-type contact and a second n-type contact overlying respective portions of the n-type layer, wherein the first and second n-type contacts are each located adjacent to the active region; and
a common p-type contact overlying the p-type layer, wherein the common p-type contact is laterally offset from each of the n-type contacts.

12. The optical element of claim 11, wherein the active region comprises a plurality of laser diodes.

13. The optical element of claim 11, wherein the substrate comprises a semi-insulating material.

14. The optical element of claim 11, further comprising an isolation groove extending entirely through the n-type layer and located peripheral to the active region.

15. The optical element of claim 11, wherein the n-type layer comprises a mesa located peripheral to the active region and the first and second n-type contacts are disposed over respective portions of the mesa.

16. The optical element of claim 15, further comprising an isolation groove located adjacent to the mesa.

17. The optical element of claim 16, wherein the isolation groove extends partially through the substrate.

18. A method comprising:
forming an active region between an n-type layer and a p-type layer;
forming a p-type contact over a substrate;
bonding the p-type layer to the p-type contact;
etching entirely through the n-type layer and the active region and partially through the p-type layer to form a plurality of isolated structures; and
forming an n-type contact over the n-type layer in each isolated structure to form a plurality of laser diodes, wherein each of the plurality of laser diodes is electrically connected to the p-type contact.

19. The method of claim 18, further comprising thinning the n-type layer prior to etching through the n-type layer.

20. The method of claim 18, wherein etching entirely through the n-type layer and the active region and partially through the p-type layer comprises an anisotropic etch.
